(19) United States
(12) Patent Application Publication
(10) Pub. No.: US 2009/0309766 A1
(43) Pub. Date: Dec. 17, 2009

(54) Mobile Electronic Apparatus

(75) Inventor: Kiyoto Shimizu, Kanagawa (JP)

Correspondence Address: HOGAN & HARTSON L.L.P., 1999 AVENUE OF THE STARS, SUITE 1400, LOS ANGELES, CA, 90067, US

(73) Assignee: KYOCERA CORPORATION, Kyoto-shi, Kyoto (JP)

(21) Appl. No.: 12/306,403

(22) PCT Filed: Apr. 27, 2007
(86) PCT No.: PCT/JP2007/059265

§ 371 Date: Aug. 12, 2009

(30) Foreign Application Priority Data
Jul. 3, 2006 (JP) 2006-183393

(51) Int. Cl. H03M 11/00

(52) U.S. Cl. 341/22

(57) ABSTRACT

Mobile electronic apparatus has a housing having an opening portion 13a, an operation key 16 arranged on an exterior face of the housing to be faced with the opening portion 13a, and a key detection unit 17 provided within the housing to be faced with the opening portion 13a, and the operation key 16 is formed to be larger than the opening portion 13a of the housing.

### CROSS REFERENCE TO RELATED APPLICATION

This application claims priority to and the benefit of Japanese Patent Application No. 2006-183393 filed on Jul. 3, 2006, the entire content of which is incorporated herein by reference.

### FIELD OF THE INVENTION

The present invention relates to a mobile electronic apparatus having an operation key.

### DESCRIPTION OF THE RELATED ART

While a cellular phone that is an example of a mobile electronic apparatus is recently demanded to have a special feature, reducing thickness of a cellular phone is regarded as an important factor as well as providing the special feature. Therefore, various techniques have been used to implement a thin cellular phone.

On the other hand, reducing a cellular phone leads to a drop of rigidity of a housing forming appearance of the cellular phone naturally. Especially, it is difficult to ensure sufficient key push durability of operation keys that are arranged on an exterior face of the housing and operated by being pushed.

As the related art for ensuring such key push durability, for example, a mobile electronic apparatus and a protection apparatus of a BGA package (see Japanese Patent Application Laid Open No. 2003-86971) and a mobile apparatus (see Japanese Patent Application Laid Open No. 2004-54661) have been known.

FIG. 7 shows related art for ensuring key push durability: (a) is a sectional view of related art 1; and (b) is a sectional view of related art 2. As shown in FIG. 7, the “mobile electronic apparatus and protection apparatus of a BGA package” (related art 1) has a micro-switch 1a controlled by an operation button 1 and mounted on a printed circuit board 2. And, circuit devices contained in BGA packages 2a, 2b are soldered on the other face of the printed circuit board 2, and BGA packages 2a, 2b are respectively pressed by projection portions 3a, 3b formed on the case 3. In other words, the invention according to related art 1 prevents soldered portions from being exfoliated owing to key push operations by making the BGA packages 2a, 2b pressed by the projection portions 3a, 3b (see (a)).

Moreover, in the mobile apparatus (related art 2), operation keys (operation buttons) 1 are arranged on the front side of the first substrate 4a, and a laminated film battery 5 is adhered to the rear side of the first substrate 4a. The second substrate 4b is adhered to the rear side of the laminated film battery 5. And, the rear side of the second substrate 4b is supported by a rib 6 formed on an inner wall of the rear case to be faced with the operation keys 1. In other words, the invention according to related art 2 ensures rigidity by adhering the laminated film battery 5 to the substrates 4a, 4b (see (b)).

Similarly, in order to ensure rigidity of a housing, there is a thin cellular phone whose housing is made of metal material such as magnesium (Mg) or the like. Moreover, in order to improve rigidity of a housing more strongly, there is a cellular phone whose housing is arranged at the back side of keys (for example, “RAZR” made by Motorola).

FIG. 8 shows an example of a structure in which a housing is arranged on a back side of keys: (a) is a conceptual view of a section; and (b) is a schematic view of a layered structure. As shown in FIG. 8, a structure in which a housing is arranged on a back side of keys includes a keypad 9 having a plurality of operation keys arranged so as to cover a plurality of key detection units 8 arranged on a light emitting unit 7a such as EL (Elector-Luminescence) arranged on a surface of the housing 7 as well as a substrate 7c arranged on a rear side of the housing 7 (see (a)). In other words, the housing 7, key detection units 8 and the keypad (key) 9 are layered in the described order (see (b)).

If the light emitting unit 7a is arranged on the rear side of the housing 7, the housing becomes a block for the light, and therefore, the keypad cannot be irradiated. Thus, the light emitting unit 7a has to be arranged on an external side of the housing 7, and connected to the substrate 7c arranged on the rear side of the housing 7 through a connection line 7d (see (a)).

### DISCLOSURE OF THE INVENTION

### Problems to be Solved by the Invention

However, in the conventional structure having the housing 7 arranged on the rear side of keys (see FIG. 8), the keypad 9, the key detection unit 8 and the housing 7 are layered. In other words, the key detection unit 8 is sandwiched between the keypad 9 and the housing 7. Therefore, in the conventional structure having the housing 7 arranged on the rear side of keys, since the pressure by a pushing operation to the keypad 9 is mostly applied to the key detection unit 8, the keypad 9 is easily damaged and it is difficult to ensure predetermined key push durability.

### Means for Solving the Problem

To solve the problem, mobile electronic apparatus according to the present invention has a housing having an opening portion; an operation key arranged on an exterior face of the housing to be faced with the opening portion; and a key detection unit provided within the housing to be faced with the opening portion, and the operation key is formed to be larger than the opening portion of the housing.

According to the present invention, the operation key has a protruding portion protruding toward the opening portion, the key detection unit has a second protruding portion protruding toward the opening portion, and at least one of the protruding portion and the second protruding portion is partially or entirely got into the opening portion. According to the present invention, a peripheral wall of the opening portion of the housing is chamfered so as to have a slope declined toward an inner part of the housing from the exterior face of the housing.

According to the present invention, the operation key has a key top exposed to the exterior face of the housing, a key rubber unit made of an elastic member provided at an inner side of the housing of the key top, and a key frame mounted between the key top and the key rubber unit.

According to the present invention, there is an aperture between the key top and the key frame.

According to the present invention, the key frame faces the housing through the key rubber unit.

According to the present invention, a substrate is layered at an inner side of the housing of the key detection unit, and a light emitting device which radiates the operation key with light through the opening portion is arranged in a face of the substrate facing the opening portion of the housing.

According to the present invention, the housing is made of metal material. According to the present invention, a concave portion is formed on the exterior face of the housing, the opening portion is formed at a base portion of the concave portion, and the key top is arranged in the concave portion.

### EFFECT OF THE INVENTION

According to the present invention, it is possible to improve key push durability.

### BRIEF DESCRIPTION OF THE DRAWINGS

FIG. 1 shows a housing portion on a key side of a cellular phone according to one embodiment of the present invention: (a) is an external perspective view in state that a keypad is mounted; and (b) is an external perspective view in state that a keypad is not mounted;

FIG. 2 is a sectional view taken along the line A-A shown in FIG. 1(a);

FIG. 3 is an enlarged view showing a region around the key detection unit of FIG. 2 when a key is not pushed;

FIG. 4 is an enlarged view showing a region around the key detection unit of FIG. 2 when a key is pushed;

FIG. 5 is an enlarged view similar to FIG. 3 when C-face-cut portions are not formed on the peripheral walls of the opening portion of the key front case;

FIG. 6 is a schematic diagram of a layered structure of the key-side housing of the cellular phone according to an embodiment of the present invention;

FIG. 7 shows related art for ensuring key push durability: (a) is a sectional view of related art 1; and (b) is a sectional view of related art 2; and

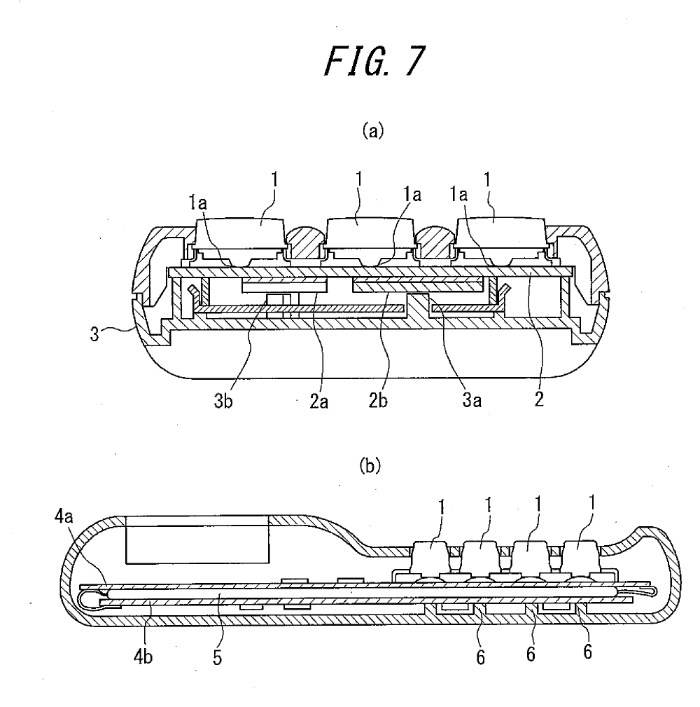

FIG. 8 shows an example of a structure in which a housing is arranged on a back side of keys: (a) is a conceptual view of a section; and (b) is a schematic view of a layered structure.

### REFERENCE SYMBOLS

10 cellular phone
11 key-side housing
12 display-side housing
13 key front case
13a opening portion
13b C-face-cut portion
14 key rear case
15 keypad
16 operation key
17 key detection unit
17a metal dome
17b film
18 light emitting device
19 battery
19a shield
20 substrate
21 key top
22 key rubber unit
22a connection portion
23 key frame
24 pusher
a space

### BEST MODE FOR CARRYING OUT THE INVENTION

Preferred embodiments of the present invention will now be described with reference to the accompanying drawings.

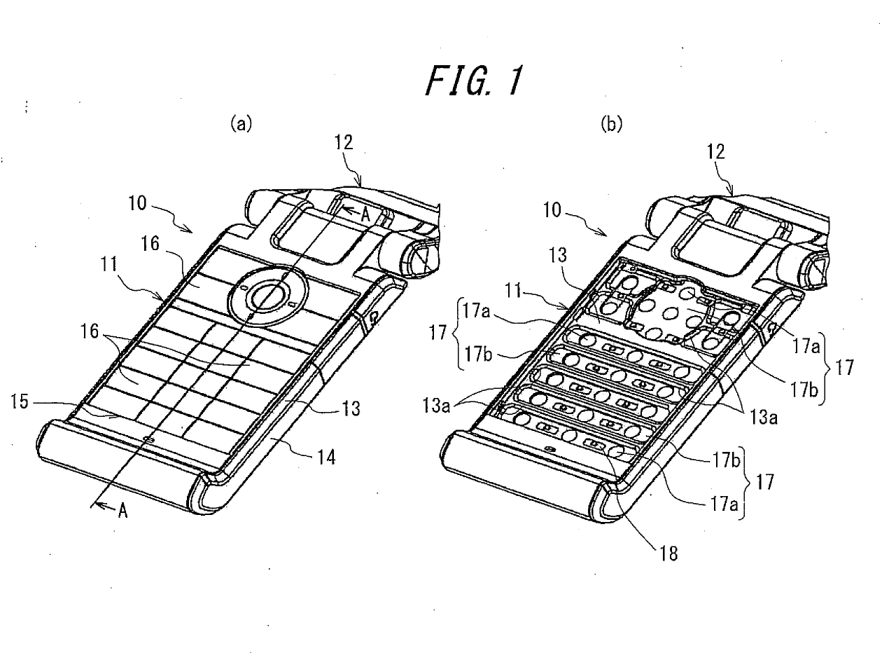

FIG. 1 shows a housing portion on a key side of a cellular phone according to one embodiment of the present invention: (a) is an external perspective view in state that a keypad is mounted; and (b) is an external perspective view in state that a keypad is not mounted. As shown in FIG. 1, a cellular phone 10 that is a mobile electronic apparatus has a key-side housing (housing) 11 and a display-side housing 12, and the key-side housing 11 and the display-side housing 12 are connected through a hinge so as to be relatively open or closed freely. A display unit (not shown) such as LCD (Liquid Crystal Display) or the like is mounted on the display-side housing 12.

The key-side housing 11 is designed so that the key front case 13 and a key rear case 14 are superposed. On the key front case 13, a keypad 15 arranged in a concave portion 25 formed on an exterior face of the key front case 13 is mounted. The keypad 15 is a component having a rectangular plate shape on which a plurality of operation keys 16 are arranged, and forms appearance on an external side of the key-side housing 11 (see (a)). In addition, each operation key 16 can be operated individually by a pushing down operation.

At base portion of a concave portion 25 of an exterior face of the key front case 13, a plurality of opening portions 13a which pierce through interior and exterior faces of the concave portion 25 are formed, and a key detection unit 17 is arranged under the key front case 13. The key detection unit 17 detects an operation status of the operation key 16, and according to the embodiment, has a metal dome sheet including metal domes 17a (second protruding portions), which are key switch portions, and a film 17b for supporting metal domes 17a. The key detection unit 17 has substantially the same plane shape with the keypad 15. Moreover, metal domes 17a are formed to protrude toward the key front case 13 with a dome shape and placed in a plurality of housings so as to correspond to respective operation keys 16.

Light emitting devices (LED) 18 are arranged on adjacent areas to metal domes 17a of the key detection unit 17 (see (b)). Each light emitting device 18 is directly connected to a substrate 20 described later and exposed to the surface of the key detection unit 17 through an opening hole on the film 17.

In other words, the opening portion 13a of the key front case 13 is formed so that one or more metal domes 17a and light emitting devices 18 faces the opening portion 13a (see (b)).

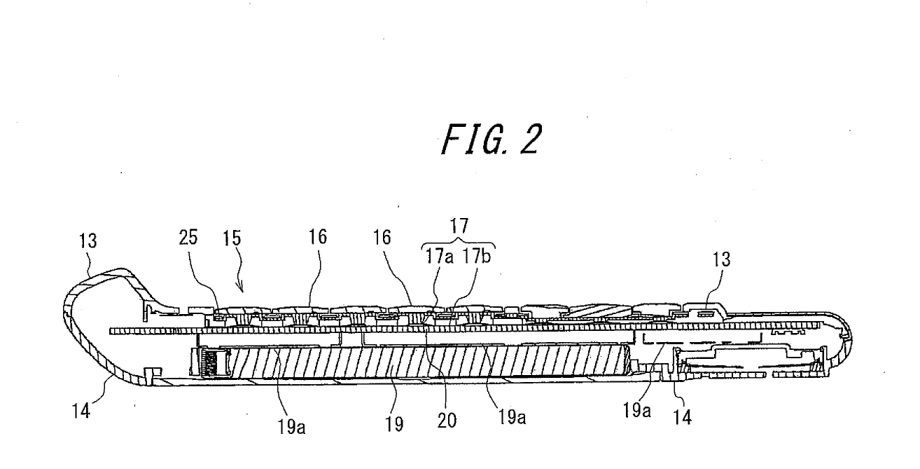

FIG. 2 is a sectional view taken along the line A-A shown in FIG. 1(a). As shown in FIG. 2, a battery 19 and the substrate 20 are contained between the key front case 13 and the key rear case 14 constructing the key-side housing 11. The key detection unit 17 is arranged on the upper face of the substrate 20, that is a face on the key front case 13 side. Moreover, a shield 19a is mounted on the upper face of the battery 19, that is a face on the substrate 20 side. In other words, the key-side housing 11 has a layered structure in which the key rear case 14, the battery 19, the substrate 20, the key detection unit 17, the key front case 13 and the keypad 15 are placed in the described order.

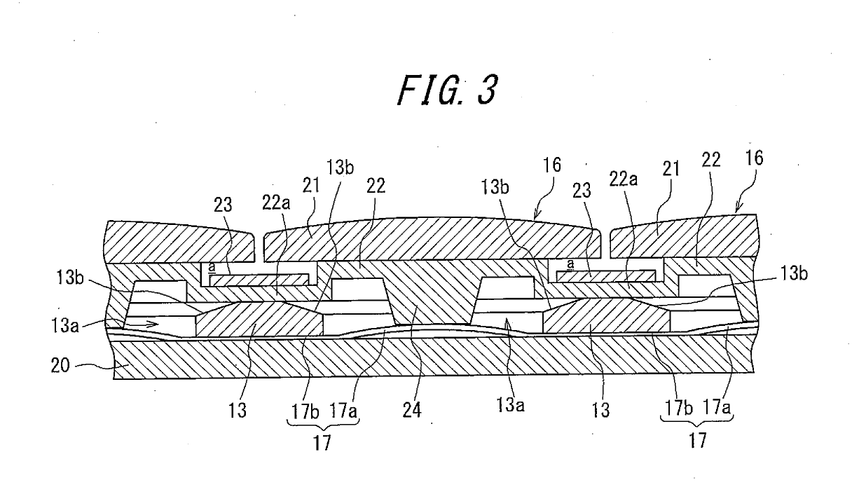

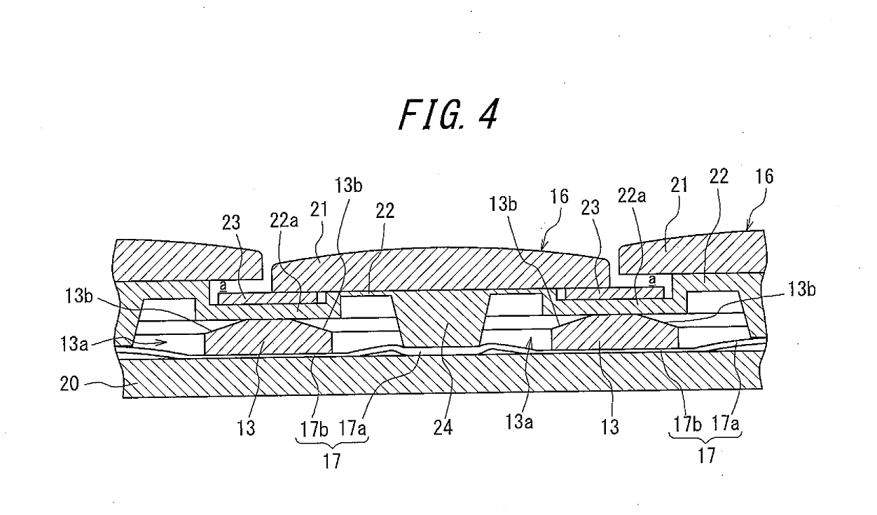

FIG. 3 is an enlarged view showing a region around the key detection unit of FIG. 2 when a key is not pushed. FIG. 4 is an enlarged view showing a region around the key detection unit of FIG. 2 when a key is pushed. As shown in FIGS. 3 and 4, the key detection unit 17 is placed on the upper face (surface) of the substrate 20, and in the key detection unit 17, metal domes 17a are respectively arranged to face the opening portions 13a. Moreover, the key detection unit 17 is arranged so that a lower face (a back side) is attached to the substrate 20. And, the key front case 13 is arranged so that a lower face (a back side) is attached to the film 17b of the key detection unit 17.

The key front case 13 is layered on the substrate 20 so that the thin film 17b of the key detection unit 17 interposes therebetween. The metal dome 17a of the key detection unit 17 is arranged to face each opening portion 13a of the key front case 13 and arranged in state of getting into each opening portion 13a in a depth direction of the key-side housing 11. Thus, thickness of layered key detection unit 17 and key front case 13 on the substrate 20 is the sum of the thickness of the key front case 13 and thickness of the thin film 17b, which is roughly the thickness of the key front case 13.

Each operation key 16 of the keypad 15 is arranged on the upper side of each metal dome 17a of the key detection unit 17 placed on the substrate 20. In other words, the operation key 16 is arranged on the exterior face of the key-side housing 11 to be faced with the opening portion 13a. In addition, the operation key 16 has a shape (area of an inner face facing the opening portion 13a) larger than the opening portion 13a (opening area). The operation key 16 has a key top 21 which forms a surface (upper face) of the keypad 15, a key rubber unit 22 formed on the back side (lower face) of the key top 21, and a key frame 23 mounted on the key rubber unit 22.

The key rubber unit 22, for example, is made of an elastic member such as rubber or the like, and is formed as one body on the whole area of the keypad 15 through a connection portion 22a that connects the key rubber unit 22 of adjacent key tops 21. A pusher (a protruding portion) 24 protruding toward the key detection unit 17 (to inside of the housing) is formed on a central portion of a lower face (back side) of the key rubber unit 22.

The connection portion 22a of the key rubber unit 22 is formed on a boundary region of adjacent key tops 21 to be apart from the key top 21 downward, as well as to make a space a between the back side of key top 21 and the key frame 23 (see FIG. 3). The key frame 23 is placed on an upper face of the connection portion 22a. In the key frame unit 23, opening portions through which the key rubber unit 22 is penetrated are formed in a region excepting the connection portion 22a vertically and horizontally.

The pusher 24 has a cylindrical shape whose end (on the inner side of the housing) has a smaller radius, and passes through the opening portion 13a of the key front case 13. The end 12 of the pusher 24 is arranged to contact to the upper end of the metal dome 17a. Thus, when the key top 21 is pushed down, the metal dome 17a is pushed by the pusher 24 and bent down (see FIG. 4). In this condition, the key detection unit 17 detects operation status of the operation key 16.

As shown in FIG. 1(b), the light emitting device 1 for emitting light is arranged on a adjacent region of a case face to each opening portion 13a of the key front case 13. Therefore, as opposed to the conventional art, the cellular phone 10 needs not to put a sheet-shaped emitting device (EL sheet or the like) on the housing as well as to form a module having both functions of key detecting device and light emitting device. Accordingly, the number of components is reduced, and key detection unit 17 is thinner than that of the conventional art.

Moreover, since the opening portion 13a is formed in the key front case 13, the light emitting device 18 can irradiate the keypad 15 directly from the lower side of the key front case 13 through the opening portion 13. Therefore, in contrast with the conventional art, the cellular phone 10 needs not to have a connection unit for connecting light emitting devices and the substrate 20. And therefore, it is possible to reduce the number of components and manufacturing processes and cut down the cost.

As shown in FIGS. 3 and 4, the space a made between the back side of the key top 21 and the key frame 23 placed on the connection portion 22a allows to ensure key push durability. In other words, when the key top 21 is pushed down, although large pressure is applied to the key top 21 toward the inner side of the housing, since the back side of the key top 21 meets the key frame 23 placed on the key front case 13 through the connection portion 22a, the key top 21 moves down only by a necessary clearance. After the key top moves down by the clearance, the key frame 23 and the key front case 13 take the pushing force to the key top 21 (see FIG. 4), so that all of the pushing force to the key top 21 is not applied to the key detection unit 17 or the substrate 20 as it is. Therefore, the substrate 20 is hardly damaged, so that it is possible to ensure key push durability.

On the peripheral walls which form the opening portion 13a of the key front case 13, C-face-cut portions 13b which are chamfered to respectively make slopes declined toward inner part of the key-side housing 11 from the exterior face (case face) of the key front case 13 are formed to improve a click feeling.

The C-face-cut portion 13b makes an aperture between the connection portion 22a and the case face so that the lower face of the connection portion 22a of the key rubber unit 22 which is attached to the case face around the opening portion 13a is not entirely attached to the case face. By the aperture being formed, when the key top 21 is pushed down, the connection portion 22a can be bent downward easily as the key top 21 moves downward. Therefore, it is possible to ensure a switch operation of the key detection unit 17 with a good click feeling. In addition, as a means to form the aperture between the connection portion 22a and the case face, it is not limited to the C-face-cut portion 13b, but it may be formed as a hollow such as a step portion or the like.

On the contrary, if the C-face-cut portions 13b are not formed around the opening portion of the key front case 13, it is difficult to acquire a good click feeling.

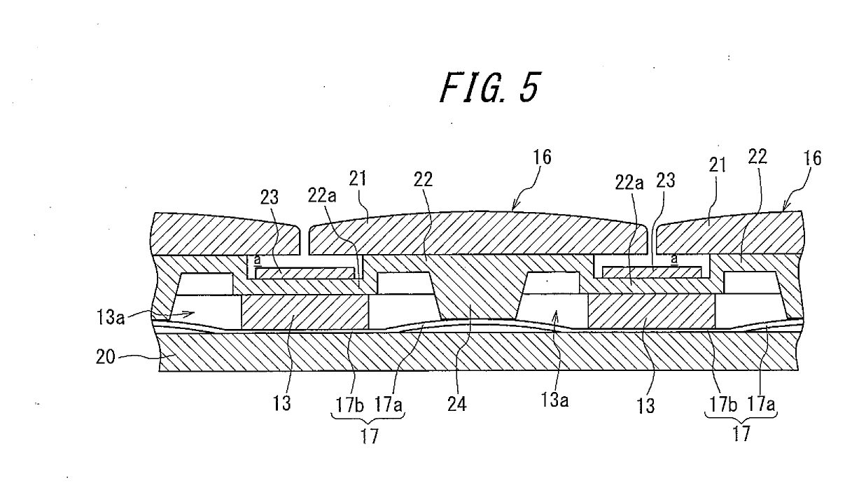

FIG. 5 is an enlarged view similar to FIG. 3 when C-face-cut portions are not formed on the peripheral walls of the opening portion of the key front case. As shown in FIG. 5, when the peripheral walls of the opening portion of the key front case 13 are not chamfered, in other words, C-face-cut portions 13b are not formed, apertures are not made between the case face around the opening portion 13a and the connection portion 22a of the key rubber unit 22, and the lower face of the connection portion 22a is attached to the case face at the whole face.

In other words, in this case, since the connection portion 22a of the key rubber unit 22 has no room to be bent, it is difficult to acquire a good click feeling. Therefore, the cellular phone 10 according to this embodiment acquires a room for the connection portion 22a to be bent in order to improve the click feeling by making C-face-cut portions 13b on the peripheral walls of the opening portion of the key front case 13.

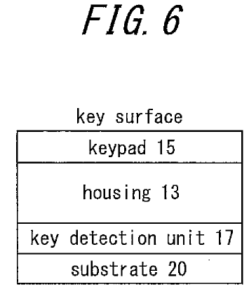

FIG. 6 is a schematic diagram of a layered structure of the key-side housing of the cellular phone according to an embodiment of the present invention. As shown in FIG. 6 and FIGS. 2, 3 and 4, the key-side housing 11 of the cellular phone 10 has the key detection unit 17, the key front case 13, and the keypad (key) 15 which are layered on the substrate 20 in the described order. However, the pusher 24 which is a protruding portion protruding toward the layered direction of the operation key 16 and the key detection unit 17, and a greater part of the metal dome 17a which is the second protruding portion protruding toward the same direction of the key detection unit 17 are arranged to get into the opening portion 13a, and therefore, the thickness of the portion got into the opening portion 13a does not affect thickness of the key-side housing 11, in other words, thickness of the entire cellular phone.

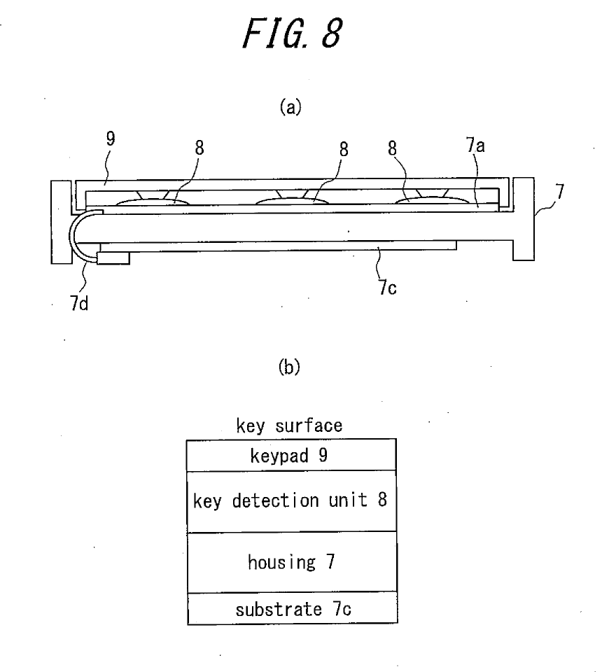

On the contrary, in the conventional structure in which the housing is arranged on the back side of keys (see FIG. 8(b)), the housing 7, the key detection unit 8 and the keypad 9 are layered on the substrate 7c in the described order, and the thickness calculated by simply adding thickness of the substrate 7c, the housing 7, the key detection unit 8 and the keypad 9 becomes the thickness of the key-side housing 11, in other words, the thickness of the entire cellular phone.

In other words, the structure of the cellular phone 10 of the present invention can be made to be thinner than the structure in which the housing is arranged on the back side of the keys by the thickness of the metal dome 17a of the key detection unit 17 and the pusher 24 of the keypad 15 which are placed inside of the key front case 13, in other words, which are got into the opening portion 13a. In addition, in this embodiment, while the pusher 24 and the greater part of the metal dome 17a are got into the opening portion 13a in the thickness direction of the housing, the present invention is not limited to this structure, but at least one of the pusher 24 and the metal dome 17a may be partially or entirely got into the opening portion 13a.

Since the key front case 13 and the key rear case 14 constructing the key-side housing 11 cover the entire housing so as to contain all kinds of components such as substrate 20 and the like, in case of making both cases 13, 14 by using metal material (for example, Mg), it is possible to prevent static electricity effectively, and since a metal housing suppresses electronic waves generated by the cellular phone 10, it is possible to decrease the Specific Absorption Rate (SAR).

As described above, since the cellular phone 10 in this embodiment has the structure in which thickness of the metal dome 17a and thickness of the pusher 24 do not affect height of layers from the substrate 20 to the keypad 15, it is possible to design a thin cellular phone, and moreover it is possible to reduce thickness of the entire set of the cell phone comparing to the conventional structure. In addition, since the light emitting unit can be arranged on the substrate 20, it is not necessary to form a light emitting unit in the key detection unit 17, so that it is possible to more reduce the thickness of the entire set of the cellular phone, and reduce the cost. Moreover, since the key front case 13 is arranged at lower side (back side) of the operation key 16, even if the key top 21 of the operation key 16 is pushed down strongly, since the key front case 13 takes the pushing force, there is no case that large force is applied to the substrate 20, and the key detection unit 17 and the substrate 20 are prevented from being damaged. Therefore, key push durability is improved.

While the invention has been described with reference to exemplary embodiments, the invention is not limited to those embodiments. For example, while the cellular phone 10 of the embodiment detects operation status of the operation key 16 when the pusher 24 pushes the metal dome 17a to be bent down, the present invention is not limited to this, but for example, to detect the operation status of the operation key 16, the key detection unit may be implemented as a distance measuring device measuring a distance from the key detection unit to the key top with infrared light or the like, and making the distance measuring device calculate a moving distance of the key top when a user pushes down the key top. With this variation, it is possible to improve the key push durability more strongly, and to realize a design in which the pusher 24 and metal dome 17a are not required. Thus, it can be expected to be thinner cellular phone. Therefore, it will be understood that variations and modifications are intended to be included within the spirit and scope of the invention.

1. Mobile electronic apparatus comprising:
a housing having an opening portion;
an operation key arranged on an exterior face of the housing to be faced with the opening portion; and
a key detection unit provided within the housing to be faced with the opening portion,
wherein the operation key is formed to be larger than the opening portion of the housing.

2. The mobile electronic apparatus according to claim 1, wherein the operation key has a protruding portion protruding toward the opening portion,
the key detection unit has a second protruding portion protruding toward the opening portion, and
at least one of the protruding portion and the second protruding portion is partially or entirely got into the opening portion.

3. The mobile electronic apparatus according to claim 1, wherein a peripheral wall of the opening portion of the housing is chamfered so as to have a slope declined toward an inner part of the housing from the exterior face of the housing.

4. The mobile electronic apparatus according to claim 1, wherein the operation key has a key top exposed to the exterior face of the housing, a key rubber unit made of an elastic member provided at an inner side of the housing of the key top, and a key frame mounted between the key top and the key rubber unit.

5. The mobile electronic apparatus according to claim 4, wherein there is an aperture between the key top and the key frame.

6. The mobile electronic apparatus according to claim 4, wherein the key frame faces the housing through the key rubber unit.

7. The mobile electronic apparatus according to claim 1, wherein a substrate is layered at an inner side of the housing of the key detection unit, and a light emitting device which radiates the operation key with light through the opening portion is arranged in a face of the substrate facing the opening portion of the housing.

8. The mobile electronic apparatus according to claim 1, the housing is made of metal material.

9. The mobile electronic apparatus according to claim 1, wherein a concave portion is formed on the exterior face of the housing
the opening portion is formed at a base portion of the concave portion, and
the key top is arranged in the concave portion.
